(19) United States
(12) Patent Application Publication
(10) Pub. No.: US 2018/0047546 A1
(43) Pub. Date: Feb. 15, 2018

(54) DRY-ETCH DEVICE AND A LOWER ELECTRODE THEREOF

(71) Applicants: BOE TECHNOLOGY GROUP CO., LTD., Beijing (CN); BEIJING BOE DISPLAY TECHNOLOGY CO., LTD., Beijing (CN)

(72) Inventors: Guangming ZHANG, Beijing (CN); Wei LI, Beijing (CN); Kai YU, Beijing (CN); Hongming QU, Beijing (CN)

(21) Appl. No.: 15/655,950

(22) Filed: Jul. 21, 2017

(30) Foreign Application Priority Data
Aug. 9, 2016 (CN) 201620857684.1

(51) Int. Cl. H01J 37/32; H01L 21/67

(52) U.S. Cl. CPC H01J 37/32541; H01L 21/67069; H01J 2237/334

(57) ABSTRACT

A dry-etch device and a lower electrode are disclosed. The lower electrode includes a body of an electrode plate and a plurality of protrusions. The body of the electrode plate has an upper surface and a lower surface opposite each other. The plurality of protrusions is provided on the upper surface of the body of the electrode plate and a surface defined by the top of each protrusion is a curved surface protruding upwardly.

### CROSS REFERENCE TO RELATED APPLICATIONS

This application claims the priority to and the benefit of Chinese Patent Application No. 201620857684.1, filed on Aug. 9, 2016 and entitled “a dry-etch device and a lower electrode thereof”, which is incorporated herein by reference in its entirety.

### TECHNICAL FIELD

The present disclosure relates generally to the technical field of producing display devices, and particularly to a dry-etch device and a lower electrode thereof.

### BACKGROUND

The dry-etch technique is that etching a film on a glass or other substrate to be etched by plasma. If the gas is in a form of plasma, on the one hand, the plasma having better chemical activity than normal state could react with material faster, thereby achieving remove during etch process. On the other hand, the plasma could be guided and accelerated by electric field so as to have energy, such that when bombarding a surface of an object being etched, the plasma could be knocked out by atom in the object being etched, thereby achieving etch by energy transfer of physics.

An existing dry-etch device includes a reactor chamber, an upper electrode and a lower electrode disposed in the reactor chamber. The operating principle of the existing dry-etch device includes the following step: locating a substrate to be etched on the lower electrode; injecting plasma gas into the reactor chamber and subsequently sealing the reactor chamber; applying voltage to the upper electrode and the lower electrode so as to form a potential difference therebetween; such that under the electric field the plasma could gain high energy so as to bombard the substrate to be etched with a high speed, thereby achieving etch.

During bombardment, in order to control etch speed, the temperature of the substrate to be etched should be controlled. Consequently, protrusions are provided at an upper surface of a body of an electrode plate of the lower electrode, on which the substrate to be etched is located. A gap layer is existed between the substrate to be etched and the body of the electrode plate, in which low temperature inert gas is blew, thereby cooling the substrate to be etched.

### SUMMARY

The embodiments of the present disclosure provide the following technical solution, so as to achieve an effect of the present disclosure.

In one aspect, the present disclosure provides a lower electrode of a dry-etch device, comprising:

a body of an electrode plate having an upper surface and a lower surface opposite each other, and

a plurality of protrusions provided on the upper surface of the body of the electrode plate, wherein a surface defined by the top of each protrusion is a curved surface protruding upwardly.

In another aspect, the present disclosure provides a dry-etch device, comprising:

a lower electrode comprising:

a body of an electrode plate having an upper surface and a lower surface opposite each other, and

a plurality of protrusions provided on the upper surface of the body of the electrode plate, wherein a surface defined by the top of each protrusion is a curved surface protruding upwardly.

### BRIEF DESCRIPTION OF THE DRAWINGS

In order to clarify technical aspects in embodiments of the present disclosure more clearly, drawings which are needed for the description of the embodiments are briefly described hereinafter. It will be apparent that the drawings in the following description are merely some embodiments of the present disclosure. Other drawings may be obtained according to these drawings by those skilled in the art, without creative labor.

FIG. 1 is a schematic diagram illustrating a structure of a lower electrode of a dry-etch device according to an embodiment of the present disclosure;

FIG. 2 is a main view illustrating an arrangement of the lower electrode of the dry-etch device according to an embodiment of the present disclosure;

FIG. 3 is a main view illustrating another arrangement of the lower electrode of the dry-etch device according to an embodiment of the present disclosure;

FIG. 4 illustrates a cross-sectional view along line A-A in FIG. 3;

FIG. 5 is a schematic diagram illustrating a structure of the lower electrode of the dry-etch device according to another embodiment of the present disclosure;

FIG. 6 is a main view illustrating still another arrangement of the lower electrode of the dry-etch device according to an embodiment of the present disclosure;

FIG. 7 illustrates a cross-sectional view along line A-A in FIG. 3 in which another arrangement of through holes is shown;

FIG. 8 illustrates a cross-sectional view along line B-B in FIG. 7.

### DETAILED DESCRIPTION

Exemplary embodiments will be specifically and completely described as follows combining with drawings. It will be appreciated that the embodiments as described are merely parts of embodiments according to the present disclosure, not the whole. Other embodiments obtained by those skilled in the art without creative labor are intended to fall within the scope of the disclosure.

Reference number: 00—body of an electrode plate; 01—protrusion; 01—through hole; h—thickness of a body of an electrode plate; C and D—group of tubes; W—height difference between the center of the curved surface defined by the top of each protrusion and the top of the lowest protrusion at the edge; and X, Y and Z—portions dividing through holes at the body of an electrode plate.

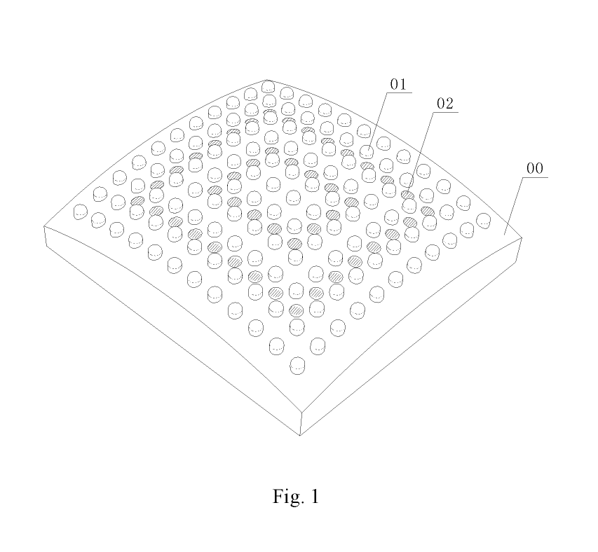

The embodiment of the present disclosure provides a lower electrode of a dry-etch device, as shown in FIG. 1, the lower electrode includes a body 00 of an electrode plate and a plurality of protrusions 01, the body 00 of the electrode plate has an upper surface and a lower surface opposite each other, the plurality of protrusions 01 are provided on the upper surface of the body 00 of the electrode plate, and a surface defined by the top of each protrusion 01 is a curved surface protruding upwardly.

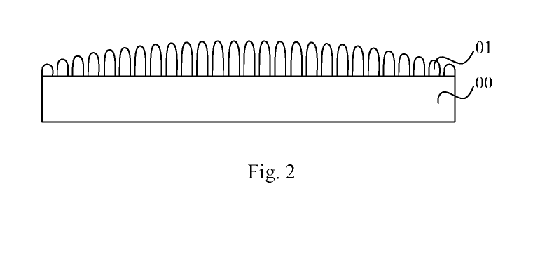

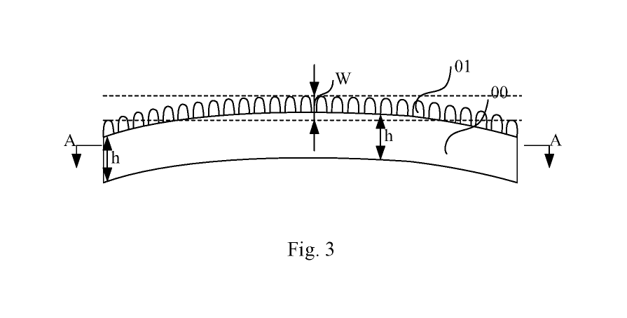

It should be noted that the aforesaid curved surface protruding upwardly refers to an upper surface of the whole lower electrode of the dry-etch device. The curved surface may be in a form as shown in FIG. 2, that is, in the case of the difference of the height existing in the protrusions 01 provided on the body 00 of the electrode plate, a surface defined by connecting the top of each protrusion 01 is the curved surface protruding upwardly; or may be in a form as shown in FIG. 3, that is, the upper surface of the body 00 of the electrode plate is designed to be a curved surface protruding upwardly, on which protrusions 01 having identical height are provided, such that a surface defined by connecting the top of each protrusion 01 forms the curved surface protruding upwardly.

The body 00 of the electrode plate mentioned in the present disclosure refers to a whole plate structure constituted by a tungsten layer having electric potential at lower electrode due to applied voltage, an upper insulation layer on the tungsten layer, and a lower insulation layer below the tungsten layer.

It should be understood that in the description of the present disclosure terms “center”, “upper”, “lower”, “front”, “back”, “left”, “right”, “vertical”, “horizontal”, “top”, “bottom” or the like indicating directions or position relation are based on the directions or position relation as shown in drawings, which are merely used for a convenient and easy description, rather than indicating or hinting that the structure or element should be configured or operated at the certain direction. Consequently, the above terms are not intended to limit the scope of the disclosure.

In addition, the plurality of protrusions 01 on the body 00 of the electrode plate could support the substrate to be etched at lower electrode, a gap is existed between the substrate to be etched and the upper surface of the body 00 of the electrode plate due to the support by the protrusions 01, in which the low temperature inert gas is passed via through holes 02 provided on the body 00 of the electrode plate, thereby cooling every area at the surface of the substrate to be etched during dry-etch process.

The embodiment of the present disclosure provides a lower electrode of a dry-etch device, the lower electrode includes a body of an electrode plate and a plurality of protrusions, the body of the electrode plate has an upper surface and a lower surface opposite each other, the plurality of protrusions are provided on the upper surface of the body of the electrode plate, and a surface defined by the top of each protrusion is a curved surface protruding upwardly. Because the surface defined by the top of each protrusion is configured to be a curved surface protruding upwardly, stress at each area between the substrate to be etched and the protrusions on the lower electrode is uniform, thereby avoiding partly abrasion with the protrusions, reducing temperature difference between each area at the substrate to be etched during dry-etch process, and improving uniformity of etch speed.

The substrate to be etched is transported to the lower electrode by a manipulator, and then goes downwards and is located on the lower electrode by lifting of supporting pins on the lower electrode. When a process is finished, the substrate to be etched is jacked away from the lower electrode, goes upwards and is transported to the next process by the manipulator. Commonly, the supporting pins are not provided corresponding to edges of the substrate to be etched, therefore, during going up and down along with the supporting pins, the substrate to be etched would occur deformation at the edges thereof due to gravity action, especially to the four corners of the substrate to be etched, a droopy deformation is the most serious, such that parts of the substrate to be etched droopingly deformed contact the corresponding protrusions 01 at the upper surface of the body 00 of the electrode plate first and are worn out seriously, which results in non-consistency of height of the protrusions 01, and a gap layer between the parts worn out seriously of the protrusions and the body 00 of the electrode plate become smaller.

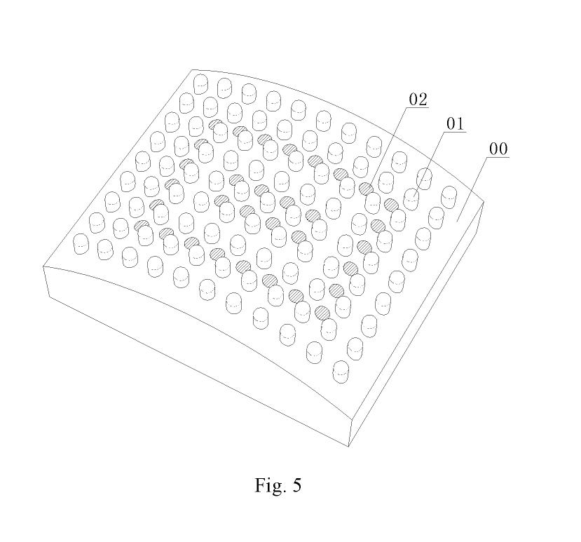

Furthermore, the curved surface protruding upwardly may be a surface of a spherical crown as shown in FIG. 1, or may be a surface of an arch as shown in FIG. 5.

The substrate to be etched is moved up and down along with the supporting pins and located on the arched surface. For example, in case that an assistant supporting rods are horizontally provided at top of the supporting pins at both ends of the same side for connecting the supporting pins, four corners of the substrate to be etched would be droopingly deformed seriously due to gravity action. The droopy deformation is smaller at two sides having assistant supporting rods due to the support function by the assistant supporting rods, while the droopy deformation is significant at the other two sides. A solution may be adopted, that is, the curved surface protruding upwardly of the lower electrode is an arched surface as shown in FIG. 5, the left and right sides of the arched surface are bent with a degree proximate to that of the deformation due to gravity action as described above, therefore, when the substrate to be etched is located on the arched surface, abrasion between the edges of the substrate to be etched and protrusions 01 at upper edges of the lower electrode could be reduced.

In case that the substrate to be etched is moved up and down by multipoint supporting of the supporting pins, four sides of the substrate to be etched would be droopingly deformed seriously due to gravity action along with four corners, and the deformation degree at four sides are similar. As shown in FIG. 1, the curved surface of the lower electrode in a form of the surface of a spherical crown is bent in a degree most similar with that of the substrate to be etched bent naturally due to gravity action during moved up and down along with the supporting pins and located. Consequently, abrasion of protrusions 01 at corresponding part due to partly contact friction between the lower electrode and the substrate to be etched could be further reduced, thereby uniformizing the abrasion degree at every part of protrusions 01 on the upper surface of the body 00 of the electrode plate, and improving uniformity of etch speed. In the following detailed embodiment and drawings, the curved surface protruding upwardly is described by taking spherical crown as an example.

Further, as shown in FIG. 2, the upper surface of the body 00 of the electrode plate is a flat surface, height of the plurality of protrusions 01 on the upper surface is decreased gradually from center to periphery so as to form the curved surface protruding upwardly.

In this way, height of the plurality of protrusions 01 thereon is decreased gradually from center to periphery, such that a surface defined by the top of each protrusion is a curved surface protruding upwardly. However, the low temperature inert gas is blew to every area at the substrate to be etched via through holes 02 provided on the body 00 of the electrode plate with passing through the gap between the body 00 of the electrode plate and the protrusions 01, if the height of the plurality of protrusions 01 is decreased gradually from center to periphery, the height of gas between each protrusion 01 and the body 00 of the electrode plate is different, which results in difference of speed of low temperature inert gas blowing from the through holes 02 to each area at the substrate to be etched, thereby affecting uniformity of temperature of whole substrate to be etched during dry-etch process.

Preferably, the upper surface of the body 00 of the electrode plate is a curved surface protruding upwardly, height of each of the protrusions 01 on the upper surface of the body 00 of the electrode plate is identical, such that a surface defined by the top of the protrusions 01 is the curved surface protruding upwardly.

In particular, a structure may be as shown in FIG. 3, that is, both the upper surface and the lower surface of the body 00 of the electrode plate are curved surfaces protruding upwardly, that is, the whole body 00 of the electrode plate protrudes upwardly from center to form the curved surface.

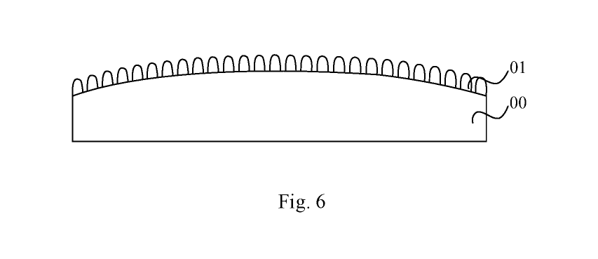

In addition, a structure may be as shown in FIG. 6, that is, the upper surface of the body 00 of the electrode plate is a curved surface protruding upwardly, while the lower surface is flat.

Preferably, as shown in FIG. 3, every area of the body 00 of the electrode plate has the same thickness h.

As shown in FIG. 1, the plurality of through holes 02 are processed on the body 00 of the electrode plate, considering the factors of saving raw material, reducing processing difficulty and overall stability of the lower electrode of the dry-etch device and so on, the design solution as shown in FIG. 3 is preferred, that is, both the upper surface and the lower surface of the body 00 of the electrode plate are curved surfaces protruding upwardly, and every area of the body 00 of the electrode plate has the same thickness h.

In addition, the lower surface of the body 00 of the electrode plate is not limited to any particular shape, which could be any other shape as needed, so long as the curved surface just meets requirement of protruding upwardly from the upper surface of the body 00 of the electrode plate. The shape described in present embodiment is only as example and not be limited.

Preferably, as shown in FIG. 3, height difference W between the center of the curved surface defined by the top of each protrusion 01 and the top of the lowest protrusion 01 at the edge is smaller than or equal to 50 mm.

If the height difference W is larger than 50 mm, the curvature of the curved surface defined by the top of each protrusion 01 is oversize. When the substrate to be etched is moved up and down along with the supporting pins and located, the curvature of the substrate to be etched in a natural-bend condition is relatively small, such that the center of the substrate to be etched contacts the protrusions 01 at the center of the lower electrode first and rubs, which results in that the protrusions at the center of the lower electrode is worn out much more seriously than other protrusions, thereby affecting uniformity of etch speed.

Concerning a substrate to be etched having a relative larger size, the supporting position of the supporting pins would be adjusted towards the edges so as to ensure the stability of the substrate to be etched on the supporting pins during location and movement. Therefore, the curvature of the substrate to be etched in a natural-bend condition will not increase with the increase of the size of the substrate to be etched. Consequently, height difference W between the center of the curved surface defined by the top of each protrusion 01 and the top of the lowest protrusion 01 at the edge should be adjusted to be smaller than or equal to 50 mm as needed.

In order to further improve uniformity of temperature of whole substrate to be etched, thereby uniformizing the etch speed at every area of the substrate to be etched during dry-etch process, and reducing the probability of embossing mura, the body 00 of the electrode plate is further provided with through holes 02 passing through the upper and lower surface of the body 00 of the electrode plate, which are in arrangement of concentric rings from center to periphery. The concentric rings are divided into a center portion and a periphery portion at least from center to periphery, and the through holes 02 at the center portion and the periphery portion are communicated with two groups of tubes respectively. The flow rate in the at least two groups of tubes may be different. In one embodiment, the flow rate in a tube communicating with the through holes 02 at the center portion is smaller than that in a tube communicating with the through holes 02 at the periphery portion. In the present embodiment, abrasion of the substrate to be etched by the protrusions 01 at edges could be reduced by controlling the flow rate in different tubes.

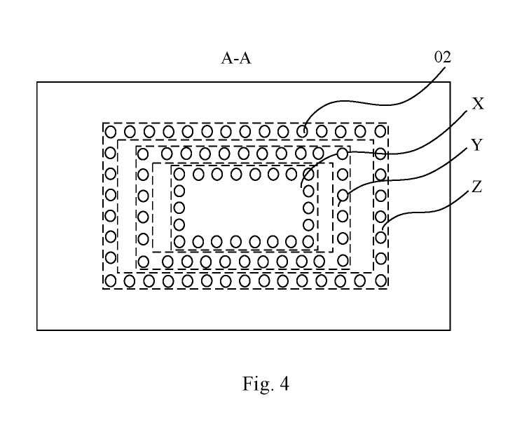

As an embodiment in FIG. 4, the through holes 02 are in arrangement of three concentric rings at the body 00 of the electrode plate, which are divided into three portions X, Y and Z from center to periphery. The through holes 02 at each portion are communicated with one group of tubes (not shown). The three portions X, Y and Z are communicated with three groups of tubes respectively, in which low temperature inert gas is passed with a flow rate that adjustable independently. With this structure, the flow rate in the through holes 02 at each divided portion could be adjusted respectively, which could counteract the difference of flow rate of the low temperature inert gas at each area of the substrate to be etched via the through holes 02, in case that the gap between each protrusion 01 at the body 00 of the electrode plate and the body 00 of the electrode plate is different due to factors such as abrasion or the like, thereby improving uniformity of temperature of whole substrate to be etched during dry-etch process.

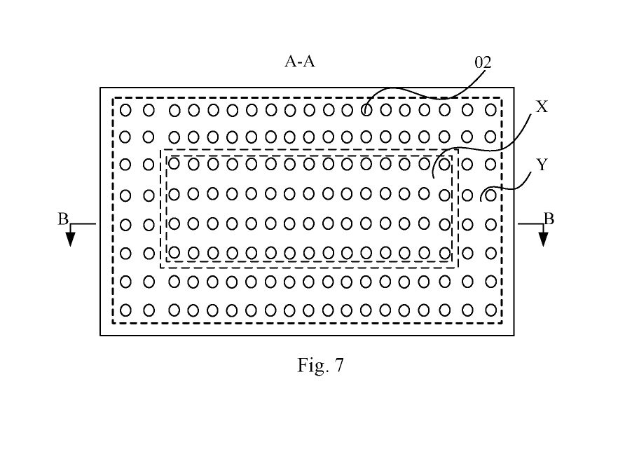

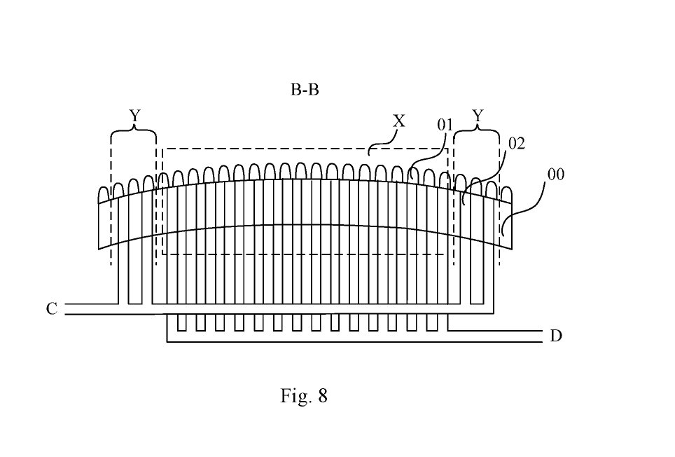

In consideration of the more the through holes 02 are divided, the more the tubes should be provided, the cost will be raised and the complexity of the operation of the lower electrode of the dry-etch device according to the present disclosure will grow, if the flow rate is adjusted by many groups of tubes respectively. Therefore, preferably, as shown in FIG. 7, concentric rings are divided into two portions X and Y from center to periphery, and as shown in FIG. 8, the through holes 02 at the two portions X and Y are communicated with two groups of tubes respectively.

For example, as shown in FIG. 8, the through holes 02 at portion X are communicated with group D of tubes, in which low temperature inert gas is passed; the through holes 02 at portion Y are communicated with group C of tubes, in which low temperature inert gas is passed. With this arrangement, low temperature inert gas in portions X and Y could be controlled to blow in different flow rate in order to cool different positions at the substrate to be etched by setting flow rate in the group C and D of tubes respectively.

In another aspect, the present disclosure provides a dry-etch device including any one of the lower electrode of the dry-etch device mentioned above.

The structure of the dry-etch device has been described in detail in the foregoing embodiment concerning the lower electrode of the dry-etch device, and the detailed description is omitted herein.

The embodiment of the present disclosure provides a lower electrode of a dry-etch device, the lower electrode includes a body of an electrode plate and a plurality of protrusions, the body of the electrode plate has an upper surface and a lower surface opposite each other, the plurality of protrusions are provided on the upper surface of the body of the electrode plate, and a surface defined by the top of each protrusion is a curved surface protruding upwardly. Because the surface defined by the top of each protrusion is configured to be a curved surface protruding upwardly, stress at each area between the substrate to be etched and the protrusions on the lower electrode is uniform, thereby avoiding partly abrasion with the protrusions, reducing temperature difference between each area at the substrate to be etched during dry-etch process, and improving uniformity of etch speed.

It will be appreciated by those skilled in the art that the disclosure is not limited the disclosed embodiments; one of ordinary skill in the art can make various changes and modifications to the present disclosure without departing from the spirit and scope of the invention. Thus, the present disclosure intends to encompass such changes and modifications provided that those changes and modifications fall within the scope of claims of the present invention and equivalents thereof.

What is claimed is:

1. A lower electrode of a dry-etch device, comprising:
a body of an electrode plate having an upper surface and a lower surface opposite each other, and
a plurality of protrusions provided on the upper surface of the body of the electrode plate, wherein a surface defined by the top of each protrusion is a curved surface protruding upwardly.

2. The lower electrode of the dry-etch device according to claim 1, wherein the curved surface is in a shape of arch or spherical crown.

3. The lower electrode of the dry-etch device according to claim 1, wherein the upper surface of the body of the electrode plate is a curved surface protruding upwardly, and the lower surface is a flat surface.

4. The lower electrode of the dry-etch device according to claim 1, wherein the upper surface of the body of the electrode plate is a flat surface, and height of the plurality of protrusions thereon is decreased gradually from center to periphery so as to form the curved surface protruding upwardly.

5. The lower electrode of the dry-etch device according to claim 1, wherein both the upper surface and the lower surface of the body of the electrode plate are curved surfaces protruding upwardly.

6. The lower electrode of the dry-etch device according to claim 5, wherein every area of the body of the electrode plate has the same thickness.

7. The lower electrode of the dry-etch device according to claim 1, wherein height difference between the center of the curved surface defined by the top of each protrusion and the top of the lowest protrusion at the edge is smaller than or equal to 50 mm.

8. The lower electrode of the dry-etch device according to claim 1, wherein the body of the electrode plate is further provided with through holes passing through the upper and lower surface of the body of the electrode plate, which are in arrangement of concentric rings from center to periphery; the concentric rings are divided into two portions at least from center to periphery, the through holes at each portion are communicated with one group of tubes, and the through holes at different portions are communicated with different group of tubes.

9. The lower electrode of the dry-etch device according to claim 8, wherein the concentric rings are divided into two portions from center to periphery, the through holes at the two portions are communicated with two groups of tubes respectively.

10. A dry-etch device, comprising:
a lower electrode comprising:
a body of an electrode plate having an upper surface and a lower surface opposite each other, and
a plurality of protrusions provided on the upper surface of the body of the electrode plate, wherein a surface defined by the top of each protrusion is a curved surface protruding upwardly.

11. The dry-etch device according to claim 10, wherein the curved surface is in a shape of arch or spherical crown.

12. The dry-etch device according to claim 10, wherein the upper surface of the body of the electrode plate is a curved surface protruding upwardly, and the lower surface is a flat surface.

13. The dry-etch device according to claim 10, wherein the upper surface of the body of the electrode plate is a flat surface, and height of the plurality of protrusions thereon is decreased gradually from center to periphery so as to form the curved surface protruding upwardly.

14. The dry-etch device according to claim 10, wherein both the upper surface and the lower surface of the body of the electrode plate are curved surfaces protruding upwardly.

15. The dry-etch device according to claim 14, wherein every area of the body of the electrode plate has the same thickness.

16. The dry-etch device according to claim 10, wherein height difference between the center of the curved surface defined by the top of each protrusion and the top of the lowest protrusion at the edge is smaller than or equal to 50 mm.

17. The dry-etch device according to claim 10, wherein the dry-etch device further comprises at least two groups of tubes, and the body of the electrode plate is further provided with through holes passing through the upper and lower surface of the body of the electrode plate, which are in arrangement of concentric rings from center to periphery; the concentric rings are divided into two portions at least from center to periphery, the through holes at each portion are communicated with one group of tubes, and the through holes at different portions are communicated with different group of tubes.

18. The dry-etch device according to claim 17, wherein the concentric rings are divided into a center portion and a periphery portion from center to periphery, the through holes at the center portion and the periphery portion are communicated with the two groups of tubes respectively.

19. The dry-etch device according to claim 17, wherein the flow rate in the at least two groups of tubes is different.

20. The dry-etch device according to claim 18, wherein the flow rate in a tube communicating with the through holes at the center portion is smaller than that in a tube communicating with the through holes at the periphery portion.
